(19) United States
(12) Patent Application Publication
(10) Pub. No.: US 2002/0106017 A1
(43) Pub. Date: Aug. 8, 2002

(54) Method for transmitting signals over a cable protocol

(76) Inventors: Kevin Eugene Dombkowski, Oswego, IL (US); Steven Mark Miller, Batavia, IL (US)

Correspondence Address: GROSSMAN, PATTI & BRILL, 300 W. WASHINGTON ST. #1200, CHICAGO, IL, 60606-2002, US

(21) Appl. No.: 09/775,994

(22) Filed: Feb. 2, 2001

(51) Int. Cl. H04N 7/173; H04J 7/00; H03K 7/08; H03K 9/08; H04B 14/04

(52) U.S. Cl. 375/238; 725/111; 725/106; 725/117; 370/212; 375/242

(57) ABSTRACT

A method according to the invention includes the steps of sending one or more upstream signals, such as voice signals, as pulse code modulated data (201) without packet headers using an upstream cable protocol and sending one or more downstream signals, such as voice signals, as pulse code modulated data (405) without packet headers using a downstream cable protocol.

### FIELD OF THE INVENTION

This invention relates to communication signals, including but not limited to transmission of signals utilizing cable protocols.

### BACKGROUND OF THE INVENTION

Standard telephone lines transport voice as pulse-code modulated (PCM) data at 1 byte per 125 microsecond interval. Over longer distances, the need for various signal modifications, such as echo cancellation, increases when the echo of an original signal occurs at time greater a certain threshold, beyond which threshold echoes are disturbing to the human ear. Long distance networks have various echo cancellation methods employed at their switches. Such methods tend to be expensive to implement and add a processing delay to signal throughput times.

Cable operators are looking to deploy real-time voice and data applications on cable protocols, in particular the DOCSIS (Data-Over-Cable System Interface Specification) protocol, over cable modems communicating at the IP (Internet Protocol) layer. Such a goal presents major challenges to delivering cost-effective high-quality real-time voice or video over cable. In such a system, cable equipment would need to support the functions of: out-of-band signalling protocols, detection of on/off hook transitions, dial-tone applications, digit collections, compensation for added delay due to packetization by supporting echo cancellation, and so forth. Such features need to be present for each end user, i.e., at the user's home, but such features are normally provided at a system switch where resources are pooled and shared across many thousands of lines, resulting in a lower cost per line. Implementing these features at each home would cost many hundreds of dollars to implement per home, with no ability to pool or share to reduce costs.

Users of the DOCSIS protocol have proposed collecting 80 samples over 10 ms, and in some cases 5 ms sample sizes, to provide echo cancellation, thereby introducing a 10 ms delay, or 5 ms for 5 ms sample sizes. Packetized data causes jitter, i.e., packets do not always arrive in fixed intervals, often causing reduction in signal quality, including voice quality for voice signals, and jitter buffers are introduced to minimize such jitter, although such buffers add delay. Because the current DOCSIS proposal for voice requires a packet structure that causes buffer delay (i.e., the 5 to 10 ms delay described above), there is a need for echo cancellation, which also introduces delay in addition to the network and playback delays involved in the proposed real-time voice-over-cable system. These delays are doubled in a two-way (round-trip) communication.

Accordingly, there is a need for a method to transport voice using cable protocols without adding unnecessary delay, and without significantly increasing equipment costs.

### SUMMARY

An apparatus for and method of transporting voice and other types of signals utilizes a cable protocol. One or more upstream signals are sent as pulse code modulated data without packet headers using an upstream cable protocol. One or more downstream signals are sent as pulse code modulated data without packet headers using a downstream cable protocol.

### BRIEF DESCRIPTION OF THE DRAWINGS

FIG. 1 is a block diagram of a cable communication system in accordance with the invention.

FIG. 2 is a timing diagram showing an upstream message mapping PCM voice information among cable protocol mini-slots in accordance with the invention.

FIG. 3 is a timing diagram showing multiple upstream messages mapping PCM voice information among mini-slots in accordance with the invention.

FIG. 4 is a diagram showing a downstream message incorporating PCM voice information within an MPEG protocol in accordance with the invention.

FIG. 5 is a diagram showing an MPEG protocol header in accordance with the invention.

FIG. 6 is a diagram showing timing of MPEG packets in accordance with the invention.

FIG. 7 is a block diagram of a media terminal adapter (MTA) in accordance with the invention.

### DESCRIPTION OF A PREFERRED EMBODIMENT

The following describes an apparatus for and method of transporting voice and other types of signals utilizing a cable protocol, such as DOCSIS, without adding unnecessary delay or jitter, but without significantly increasing equipment costs. The present invention also provides benefits with other protocols, for example, by providing for headerless streamed packets. PCM voice information is inserted in the cable protocol without headers and without packetizing the PCM voice, thereby reducing delays and bandwidth necessary to transmit the headers. Reduced delay and bandwidth allows less-complex circuitry, because functions such as echo cancellation need not be provided at the home, and hence less expensive equipment to be provided at each home.

Generally, a method according to the invention comprises the steps of sending one or more upstream signals, such as voice or video signals, as pulse code modulated data without packet headers using an upstream cable protocol and sending one or more downstream signals, such as voice or video signals, as pulse code modulated data without packet headers using a downstream cable protocol. In one method of the present invention, at least one voice signal is sampled at a voice sampling interval, yielding pulse code modulated (PCM) data, and the PCM data is transported without packet headers over a cable media using an upstream cable protocol. In another method of the present invention, at least one voice signal is provided at a voice sampling interval, yielding pulse code modulated (PCM) data, and the PCM data is transported without packet headers over a cable media using a downstream cable protocol.

The upstream and downstream protocols may be the DOCSIS protocol. One or more pulse code modulated samples of the one or more signals taken at a sampling interval may be mapped to an allocation of mini-slots in the upstream protocol. The sampling interval may be 125 microseconds and the mini-slots may occur at 6.25 microsecond intervals. Two or more signals may be multiplexed in one mini-slot in the upstream protocol. One or more pulse code modulated samples of the one or more signals taken at a sampling interval may be mapped to a Motion Pictures Experts Group (MPEG) transport layer. Multiple signals, such as voice, data, and/or video, may be multiplexed within a single MPEG packet identifier. In the preferred embodiment, the method is performed in a cable system having a media terminal adapter (MTA), such that subscriber signalling functionality is reduced in the MTA.

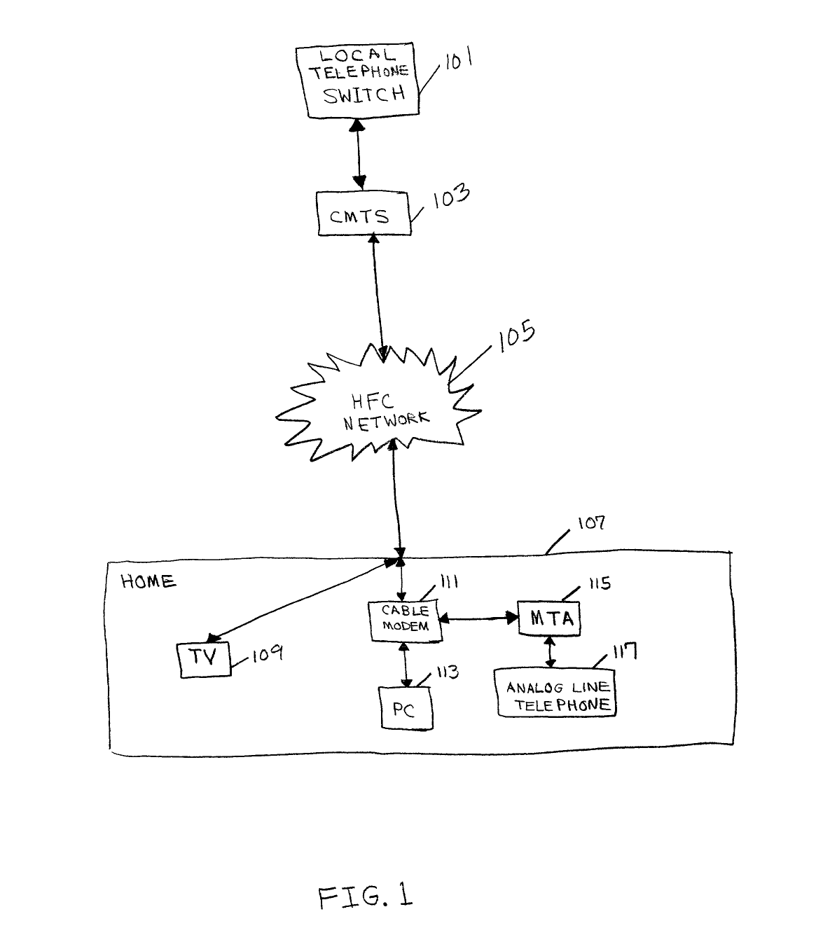

A block diagram of a cable communication system is shown in FIG. 1. A local telephone switch 101, such as a Class 5 Switch available from Lucent, Inc., is connected to a Cable Modem Termination System (CMTS) 103. The CMTS 103 controls the timing when slots of information packets are sent. The CMTS 103 is connected to a Hybrid Fiber Coax (HFC) Network 105, which is a cable TV plant with bi-directional capability, as is known in the art. The CMTS 103 and HFC Network 105 communicate with each other using the DOCSIS protocol at 6 MHz. The HFC Network 105 is coupled to a plurality of homes (one home 107 is shown for the sake of simplicity) via cable utilizing the DOCSIS protocol, as is known in the art.

The HFC network 105 terminates at a junction box (shown at the intersection of arrows) at the home 107. The cable signal is split off to a television (TV) 109 and a cable modem 111 that translates from an ethernet protocol to HFC compatible messaging. The cable modem 111 translates data, for example, for a personal computer 113 and a media transport adaptor (MTA) 115, also known as a broadband telephony interface. In one example of the present invention, the MTA 115 utilizes a Subscriber Line Interface Chip (SLIC) to provide analog-to-digital (A/D) and digital-to-analog (D/A) conversions for upstream (away from the telephone 117) and downstream (toward the telephone 117) messages, respectively, between a standard telephone 117 on an analog line and the cable modem 111 for transport to and from the HFC Network 105. The MTA 115 converts ethernet data; supplies ringing voltages for the analog line telephone 117; identifies on-hook/off-hook transitions, collects 125 μs PCM voice samples when the phone is off-hook, and forwards them to the CMTS 103 over the DOCSIS protocol, and provides other low-level hardware functions, while deferring other advanced features, such as digit detection/collection and analysis to the switch 101.

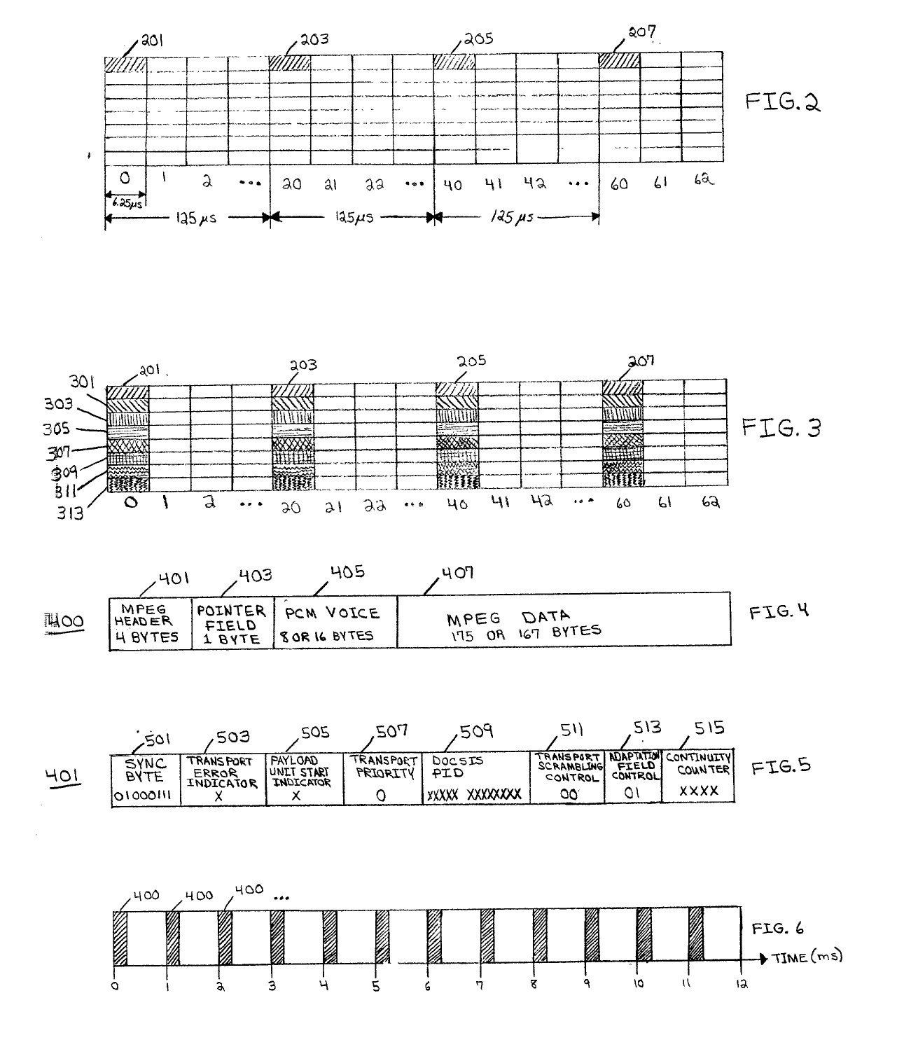

The upstream protocol utilizes FDMA (Frequency Division Multiple Access) or TDMA (Time Division Multiple Access) burst modulation format that provides two modulation formats, QPSK (Quadrature Phase Shift Keying) and 16QAM or 64QAM (Quadrature Amplitude Modulation). The mini-slot formats shown in FIG. 2 and FIG. 3 support a wide variety of bit rates, bandwidths, or payload options, although the number of bits per message remains constant. Each mini-slot may send 1, 2, 4, 8, or 16 symbols. Each symbol may contain 2 bits (QPSK), 4 bits (16QAM), 6 bits (64QAM), or 8 bits (256QAM). For example, a small bit rate comprises 1 QPSK symbol, providing:

2 (bits/symbol)×1 (symbol/mini-slot)×160,000 (mini-slots/second)=320,000 bps,

whereas a fast bit rate comprises 16 256QAM symbols, providing:

8 (bits/symbol)×16 (symbols/mini-slot)×160,000 (mini-slots/second)=20,000,000 bps.

A timing diagram showing an upstream message mapping PCM voice information among cable protocol mini-slots is shown in FIG. 2. The upstream DOCSIS protocol provides mini-slots comprised of 8 bytes of data every 6.25 microseconds (μs). In a standard telephone message, one byte (8 bits or samples) of PCM data is sampled from the voice signal at a voice sampling interval of 125 μs. The present invention takes that byte of information and inserts it as PCM data 201 in one of the 8 bytes of one of the mini-slots. One byte of PCM data is collected for each voice message every 125 μs, thus PCM data 201, 203, 205, and 207 is inserted in one of the 8 bytes of a mini-slot every 125 μs or in every 20th mini-slot.

In the event multiple signals, such as voice signals and/or computer signals, are desired to be sent simultaneously from the same home, multiple bytes 201, 301, 303, 305, 307, 309, 311, and 313 may be multiplexed into a mini-slot to transport these messages, as shown in the upstream protocol shown in FIG. 3.

The downstream physical media utilizes 64QAM or 256QAM supporting a variable-depth interleaver. The downstream protocol is comprised of 188-byte MPEG (Motion Picture Experts Group) packets transported at approximately 10 MHz as described in the DOCSIS protocol.

A diagram showing a downstream message incorporating or multiplexing PCM voice information within an MPEG protocol 400 is shown in FIG. 4. An MPEG header 401 comprises 4 bytes and is described in greater detail with respect to FIG. 5 and its associated text. A pointer field 403 is used to identify where shared data begins in the message. A PCM voice field 405 provides 8 1-byte voice samples in the preferred embodiment in order to minimize delay. The MPEG data field 407 contains the remaining information to be transmitted, such as other voice messages or data messages, either 167 bytes (when 16 bytes of voice are sent in the PCM voice field 405) or 175 bytes (when 8 bytes of voice are sent in the PCM voice field 405).

A diagram showing an MPEG protocol header 401 is shown in FIG. 5. A sync byte 501 is utilized by a receiving device, i.e., any downstream device that receives the message and needs to synchronize, such as a CMTS 103, HFC network 105 device, cable modem 111, MTA 115, or phone 117, to synchronize to and identify the beginning of each MPEG packet. A transport error indicator 503 is a single bit that indicates whether (1) or not (0) there is an error in the transport layer. A payload start indicator 505 is a single bit that indicates whether a pointer field 403 follows the MPEG header 401. A transport priority bit 507 is set to 0 in a reserved field with no declared meaning. A DOCSIS packet identifier (PID) 509 is used to identify the type of data being sent in this MPEG packet. The present invention proposes using an unused, but reserved, 13-bit code different than the current code (11111 11111110) for the DOCSIS PID 509 to signify a special priority compound PCM voice and data packet. A transport scrambling control field 511 comprises two bits set to 00, in a reserved field. An adaptation field control field 513 comprises two bits set to 01, in a reserved field. A continuity counter field 515 comprises four bits that comprise the count from 0 to 15 of a cyclic counter that is increased by 1 as each packet is transmitted. As packets are received, the receiving device checks the sequence of the continuity field and if that sequence is out of order, the receiver knows that packets were lost.

A diagram showing timing of MPEG packets is shown in FIG. 6. An MPEG packet 400 is transported in each 1 ms frame. Additional information, such as other messages in the form of MPEG streams, including voice or data, may be transmitted between the MPEG packets 400 for each voice message.

In both the upstream and downstream message protocols, packet headers, including information such as IP and UDP (User Datagram Protocol) headers, are suppressed when sending PCM data. Other data-over-cable protocols have described packetizing PCM voice information with headers necessary for transport of the PCM voice as packets. The present invention does not require the transmission of headers because the CMTS 103 emits the PCM streams into standard Class 5 trunk interfaces that do not require packet headers because the information is sorted into individual circuits. Thus, the present invention places PCM information directly into the DOCSIS protocol without packetizing, thereby reducing delay and bandwidth needed to transmit the information. As a result, jitter buffers may be shorter as a well. As well as reaping the benefits of having shorter delays and removing the overhead header packets, such as improving voice quality over existing transport methods, the MTA 115 need not provide subscriber signalling functions such as echo cancellation, jitter buffering, digit collection, and tone generation, because the MTA 115 may rely on the local switch 101 to supply these services much like subscriber loop carrier, thereby resulting in a less complicated and far less expensive MTA 115 for use in the home. Instead, these subscriber signalling functions need not be provided until the signal reaches the local telephone switch 101, which already has provisions for subscriber signalling functions.

An example of a call flow in accordance with the present invention is as follows. The MTA 115 detects an off/on hook transition and sends a message top the CMTS 103 announcing the off/on hook transition. This message may be transmitted over mini-slots, as described above, or via other communication protocols, such as UDP, or other cable modem CMTS communication methods. The CMTS 103 forwards the message to a call agent, such as a local telephone switch 101, where a dedicated PCM channel is allocated to a network component that enables generation of dial tone and digit collection. The call agent 101 signals back to the CMTS 103 with a dedicated timeslot to use in support of the calling party. The CMTS 103 then utilizes the TDM (time-division multiplexed) channel information to allocate the appropriate mini-slots and MPEG streams for communication with the MTA 115. The CMTS 103 forwards the mini-slot information to the MTA 115, where the MTA 115 synchronizes PCM sampling with the mini-slots and starts transmitting voice samples. At the same time, the MTA 115 starts retrieving PCM samples carried on an MPEG stream and starts playback on an appropriate line (e.g., dial tone is carried from the local telephone switch 101 to the phone as PCM data. The phone 117 is now connected, sharing PCM data with the network component to apply dial tone and collect digits. As the customer dials the phone 117, the MTA does not have to perform digit collection, but simply collects PCM samples and forwards them to the network component, which applies dial tone and collects digits as needed for the call flow based on the customer's dialing plan. Once all digits are collected and passed to the call agent 101, the call agent 101 routes the call and moves the PCM stream coming from the MTA 115 to the TDM switch 101, where the TDM stream is routed based on the called number. Once the call is completed and the MTA 115 detects an on-hook condition, the MTA 115 sends a message to the switch 101 and call processing proceeds based on the customer's call features.

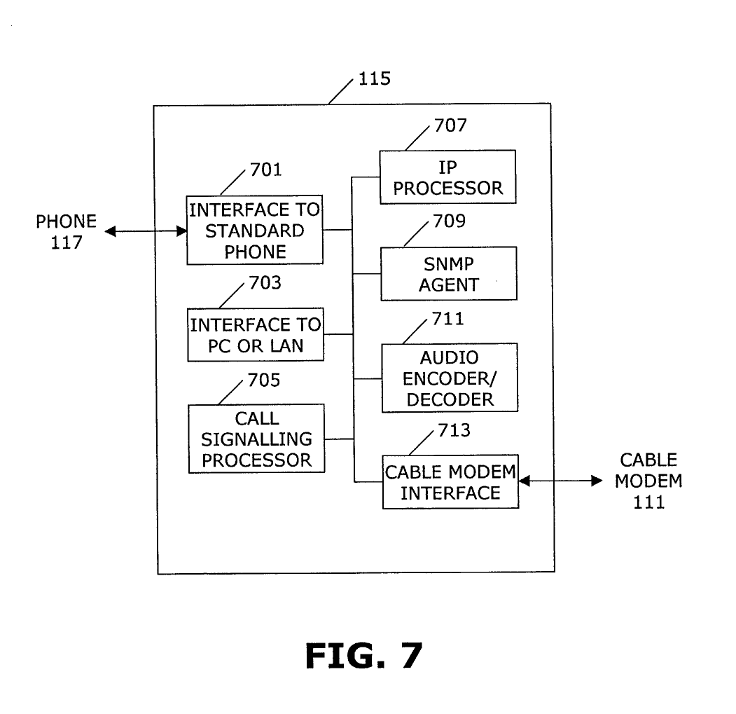

A block diagram of an example of an MTA 115 is shown in FIG. 7. In the preferred embodiment, the MTA 115 is a hardware device that interfaces analog phones with a packet-network. An MTA terminates, typically through standard RJ11 jacks, any of the following devices (each potentially equipped with its own directory number): facsimile machine, personal computer with an analog modem, and analog phones. The MTA 115 comprises an interface 701 to a standard phone, such as an analog phone 117, which interface provides a standard analog interface with traditional BORSCHT functions (for example, battery feed, over-voltage protection, supervision, coding and decoding, testing, ringing, as are known in the industry), frequency shift keying (FSK) to support, for example, caller ID features, and dual-tone multi-frequency (DTMF) functionality. The interface 701 includes a sampler that takes samples of signals at a sampling interval, yielding pulse code modulated (PCM) data.

The MTA 115 includes an interface 703 to a PC (personal computer) or LAN (local area network), such as a 10BaseT interface as known in the art. A call signalling processor 705 adapts POTS (plain old telephone system) analog signalling into message-based signaling, e.g., network-based call signalling, such as described in standard H.32. The call processor 705 also generates call progress tones and detects facsimile and modem tones to forward to a call agent. In the preferred embodiment, however, generation of call progress tones and detection of facsimile and modem tones is performed at the local switch 101 in the preferred embodiment. Also included are an SNMP (Simple Network Management Protocol) agent 709, to support performance, fault management, and configuration, and an IP processor 707 as known in the art.

An audio encoder/decoder 711 performs A/D (analog to digital) and D/A (digital to analog) conversion for the voice-band according to various CODEC schemes, e.g., G.711 or a lower bit-rate CODEC, such as G.729A, as requested by the call agent. The encoder/decoder 711 collects/unpacks voice samples into/out from IP packets according to RTP/UDP/IP (the MTA may be provisioned to support voice packets of various lengths), and sends/receives voice packets to/from the Cable Access Network and the network. This capability includes jitter buffer management and near-end echo cancellation, although the majority of this functionality is differed to the local switch 101 in the preferred embodiment. A cable modem interface 713 inserts PCM data into a transport protocol, such as DOCSIS, as shown in FIG. 2 and FIG. 3, for transport of the PCM data without packet headers over a cable media using an upstream cable protocol.

The MTA 115 of the present invention is simpler than prior MTAs because advanced features, such as digit detection/collection and analysis and echo cancellation, are differed to the local switch 101. As a result of not having these features in the MTA 115, the MTA does not require as much buffering, and overall delays in signal throughput are realized. In addition, the MTA 115 is a much less expensive piece of equipment than MTAs that include these features.

Although the above description of the present invention was given in the context of a voice application, the same principles and techniques described herein may be applied to other applications that require constant delay and/or low jitter, such as video, thereby providing benefit to such applications. The techniques are similar for such applications, although the payload (number of bytes transmitted per unit time) may differ. In addition, although the present invention is described as embodied utilizing the DOCSIS protocol, the present invention may be successfully practiced with other protocols, including other cable protocols.

The present invention provides a mechanism for reducing delays and bandwidth necessary for transporting voice and other types of signals, such as video, over cable networks. As a result, expensive and delay-causing features, such as echo cancellation and jitter buffering, need not be provided locally, thus making an MTA 115 much less expensive for use in the home. Use of the present invention results in a higher quality of signal, such as voice quality or video quality, which a customer perceives as a higher quality connection. Although the invention is ideally implemented utilizing the DOCSIS protocol, it may be successfully implemented with other protocols.

The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes that come within the meaning and range of equivalency of the claims are to be embraced within their scope.

What is claimed is:

1. A method comprising the steps of:
sending one or more upstream signals as pulse code modulated data without packet headers using an upstream cable protocol; and
sending one or more downstream signals as pulse code modulated data without packet headers using a downstream cable protocol.

2. The method of claim 1, wherein the upstream protocol is DOCSIS, Data-Over-Cable System Interface Specification.

3. The method of claim 1, wherein the step of sending one or more upstream signals comprises mapping one or more pulse code modulated samples of the one or more signals taken at a sampling interval to an allocation of mini-slots in the upstream protocol.

4. The method of claim 3, wherein the sampling interval is 125 microseconds and the mini-slots occur at 6.25 microsecond intervals.

5. The method of claim 1, further comprising the step of multiplexing two or more signals in one mini-slot in the upstream protocol.

6. The method of claim 1, wherein the downstream protocol is DOCSIS, Data-Over-Cable System Interface Specification.

7. The method of claim 1, wherein the step of sending one or more downstream signals comprises mapping one or more pulse code modulated samples of the one or more signals taken at a sampling interval to a Motion Pictures Experts Group (MPEG) transport layer.

8. The method of claim 1, wherein the step of sending one or more downstream signals comprises multiplexing multiple signals within a single Motion Pictures Experts Group (MPEG) packet identifier.

9. The method of claim 1, wherein the method is performed in a cable system having a media terminal adapter (MTA), such that subscriber signalling functionality is reduced in the MTA.

10. The method of claim 1, wherein the method reduces throughput delay and jitter for signals, thereby improving signal quality over existing transport methods.

11. The method of claim 1, wherein at least one of the one or more upstream signals and the one or more downstream signals is a voice signal.

12. The method of claim 1, wherein at least one of the one or more upstream signals and the one or more downstream signals is a video signal.

13. A method comprising the steps of:
sampling one or more signals at a sampling interval, yielding pulse code modulated (PCM) data; and
transporting the PCM data without packet headers over a cable media using an upstream cable protocol.

14. The method of claim 13, wherein the upstream protocol is DOCSIS, Data-Over-Cable System Interface Specification.

15. The method of claim 13, wherein the step of sampling the one or more signals comprises mapping each byte of pulse code modulated data to one of a plurality of mini-slots in the upstream protocol.

16. The method of claim 15, wherein the sampling interval is 125 microseconds and each of the plurality of mini-slots occurs at 6.25 microsecond intervals.

17. The method of claim 13, further comprising the step of multiplexing two or more signals in one mini-slot in the upstream protocol.

18. The method of claim 13, wherein the method reduces throughput delay and jitter for signals, thereby improving signal quality over existing transport methods.

19. The method of claim 13, wherein at least one of the one or more signals is a voice signal.

20. The method of claim 13, wherein at least one of the one or more signals is a voice signal.

21. A method comprising the steps of:
providing one or more signals at a sampling interval, yielding pulse code modulated (PCM) data; and
transporting the PCM data without packet headers over a cable media using a downstream cable protocol.

22. The method of claim 21, wherein the downstream protocol is DOCSIS, Data-Over-Cable System Interface Specification.

23. The method of claim 21, wherein the step of providing the one or more signals comprises mapping each byte of pulse code modulated data to a Motion Pictures Experts Group (MPEG) transport layer.

24. The method of claim 21, wherein the step of providing the one or more signals comprises multiplexing multiple signals within a single Motion Pictures Experts Group (MPEG) packet identifier.

25. The method of claim 21, wherein the method reduces throughput delay and jitter for signals, thereby improving signal quality over existing transport methods.

26. The method of claim 21, wherein at least one of the one or more signals is a voice signal.

27. The method of claim 21, wherein at least one of the one or more signals is a voice signal.

28. An apparatus comprising:
a sampler, arranged and constructed to sample one or more signals at a sampling interval, yielding pulse code modulated (PCM) data; and
a transport device, arranged and constructed to transport the PCM data without packet headers over a cable media using an upstream cable protocol.

29. The apparatus of claim 28, wherein the upstream protocol is DOCSIS, Data-Over-Cable System Interface Specification.

30. The apparatus of claim 28, wherein the step of sampling the one or more signals comprises mapping each byte of pulse code modulated data to one of a plurality of mini-slots in the upstream protocol.

31. The apparatus of claim 30, wherein the sampling interval is 125 microseconds and each of the plurality of mini-slots occurs at 6.25 microsecond intervals.

32. The apparatus of claim 28, further comprising a multiplexor for multiplexing two or more signals in one mini-slot in the upstream protocol.

33. The apparatus of claim 28, wherein the apparatus reduces throughput delay and jitter for signals, thereby improving signal quality over existing transport methods.

34. The apparatus of claim 28, wherein at least one of the one or more signals is a voice signal.

35. The apparatus of claim 28, wherein at least one of the one or more signals is a voice signal.

36. The apparatus of claim 28, wherein the apparatus is part of a media terminal adapter.
